(19) United States
(12) Patent Application Publication
(10) Pub. No.: US 2026/0075795 A1
(43) Pub. Date: Mar. 12, 2026

(54) DYNAMIC RANDOM ACCESS MEMORY DEVICES AND METHODS FOR MANUFACTURING THE SAME

(71) Applicant: Winbond Electronics Corp., Taichung City (TW)

(72) Inventors: Shuo-Ting YOU, Tainan City (TW); Hsuan-Tung CHU, Tainan City (TW); Wei-Che CHANG, Taichung City (TW)

(21) Appl. No.: 19/323,712

(22) Filed: Sep. 9, 2025

(30) Foreign Application Priority Data
Sep. 9, 2024 (TW) 113134066

(51) Int. Cl. H10B 12/00

(52) U.S. Cl. CPC H10B 12/09; H10B 12/482; H10B 12/50

(57) ABSTRACT

A DRAM device includes a substrate, bit lines, node contact plugs, dummy bit lines, a dummy insulating structure, and a cap layer. The substrate includes an array region, a peripheral region and a dummy region between the array region and the peripheral region. The bit lines are over the substrate and in the array region. The node contact plugs are in the array region. Each of the node contact plugs is on the substrate at one side of a corresponding one of the bit lines. The dummy bit lines are over the substrate and in the dummy region. The dummy insulating structure is between the dummy bit lines. The dummy insulating structure is arranged along with the node contact plugs. The cap layer is outside the array region to cover top portions of the dummy bit lines and top portion of the dummy insulating structure.

### CROSS REFERENCE TO RELATED APPLICATIONS

This Application claims priority of Taiwan Patent Application No. 113134066, filed on Sep. 9, 2024, the entirety of which is incorporated by reference herein.

### BACKGROUND OF THE INVENTION

### Field of the Invention

The present invention relates to semiconductor memory devices and methods of manufacturing the same, and in particular, it relates to a dynamic random access memory device capable of reducing the number of dummy bits and methods of manufacturing the same.

### Description of the Related Art

As the size of dynamic random access memory (DRAM) decreases, manufacturing DRAM becomes more challenging, requiring adjustments in structure to maintain yield. For example, in the process of defining the bit line structure in the array region, during the removal of the sacrificial oxide layer between the bit line structures in the array region, a photoresist pattern is formed to expose the array region while masking areas outside the array region. However, the etchant may penetrate from the edge of the photoresist pattern along the bottom to underneath the photoresist pattern, potentially removing the sacrificial oxide layer beneath the photoresist pattern that is intended to remain. This process may extend the array region beyond its intended boundaries and affect yield. To address this issue, a conventional DRAM process defines the opening of the photoresist pattern smaller than the target array region. This increases dummy bit structures to prevent the array region from expanding beyond its intended area. However, this approach sacrifices the number of active bits. Furthermore, as product specifications vary, the coverage position of the photoresist pattern needs to be readjusted according to the penetration characteristics of the etchant, which increases process complexity and development time. In addition, as the size of DRAM decreases, it becomes more difficult to precisely control the area of the array region, thereby reducing the yield of the DRAM.

### BRIEF SUMMARY OF THE INVENTION

The DRAM device and the manufacturing method thereof proposed in the disclosure address the problem of etchant penetration, thereby reducing the use of dummy bits and increasing the yield.

Some embodiments of the present disclosure provide a DRAM device includes a substrate, bit lines, node contact plugs, dummy bit lines, a dummy insulating structure, and a cap layer. The substrate includes an array region, a peripheral region and a dummy region between the array region and the peripheral region. The bit lines are over the substrate and in the array region. The node contact plugs are in the array region. Each of the node contact plugs is on the substrate at one side of a corresponding one of the bit lines. The dummy bit lines are over the substrate and in the dummy region. The dummy insulating structure is between the dummy bit lines. The dummy insulating structure is arranged along with the node contact plugs. The cap layer is outside the array region to cover top portions of the dummy bit lines and top portion of the dummy insulating structure.

Some embodiments of the present disclosure provide a method for manufacturing a DRAM device. The method includes forming a plurality of bit line structures over a substrate in an array region and in a dummy region outside the array region. The method further includes forming an insulating material layer between the bit line structures. The method further includes forming a cap layer in the dummy region and exposing the array region. The bit line structures covered by the cap layer forms a plurality of dummy bit lines. The bit line structures exposed by the cap layer forms a plurality of bit lines. The insulating material layer covered by the cap layer forms a dummy insulating structure. The method further includes removing the insulating material layer exposed by the cap layer to form a plurality of node contact holes in the array region. The method further includes forming a plurality of node contact plugs in the node contact holes. Each of the node contact plugs located on the substrate at one side of a corresponding one of the bit lines. The dummy insulating structure is arranged along with the node contact plugs.

The DRAM device and the manufacturing method thereof provided in the present disclosure forms a cap layer to seal top portions of the dummy bit line and the dummy insulating structure in the dummy region to block etchant penetration. This accurately defines the area of the array region, increases active bits, decreases dummy bits, and supports process scaling.

### BRIEF DESCRIPTION OF THE FIGURES

FIG. 1 is a partial top view of an array region and a peripheral region of a DRAM device in one of the manufacturing steps according to some embodiments of the present disclosure.

FIGS. 2, 3, 4, 5A, 5B, 6A, 6B, 7A, 7B, 8, and 9 are schematic diagrams of a DRAM device at various intermediate manufacturing stages according to some embodiments of the present disclosure. FIGS. 2, 3, 4, 5A, 6A, and 7A are partial stereoscopic views of the DRAM device. FIGS. 5B, 6B, 7B, 8, and 9 are partial cross-sectional views of a DRAM device, for example, along the line A-A in FIG. 1.

FIG. 10 is a schematic cross-sectional view of an intermediate manufacturing stage of a DRAM device according to some embodiments of the present disclosure.

FIG. 11 is a partial top view of an array region and a peripheral region of a DRAM device according to some embodiments of the present disclosure.

### DETAILED DESCRIPTION OF THE INVENTION

The following content provides many different embodiments for implementing different features of the embodiments of the present invention. Of course, these are merely examples and are not intended to limit the present invention. Furthermore, when it is mentioned in the description that a first element is formed above or located on a second element, unless otherwise specifically excluded, it may mean that the first element and the second element are in direct contact or not in direct contact. In addition, for the purpose of simplicity and clarity, the embodiments of the present invention may use the same or similar numeral references for the same or similar elements in many examples, and may only show a portion of the DRAM device related to the present invention.

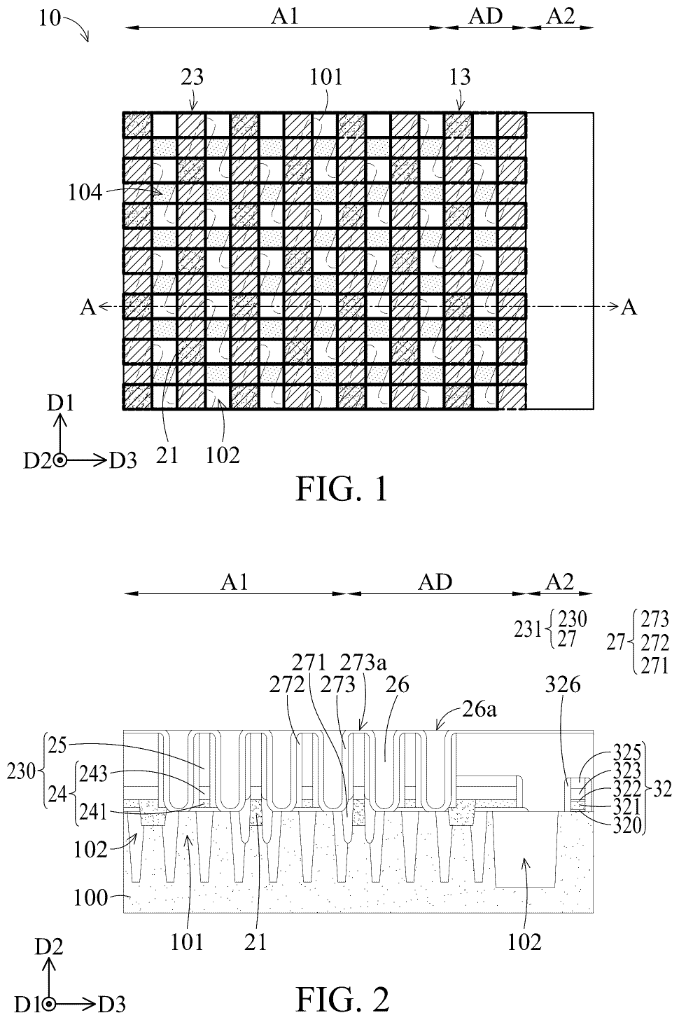

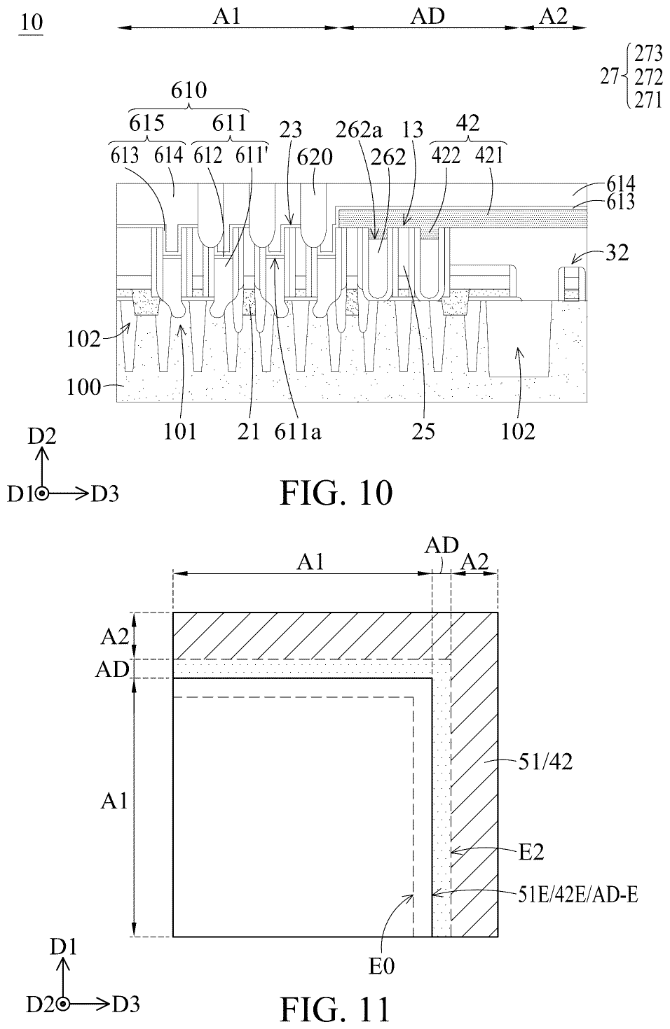

A DRAM device and a manufacturing method thereof according to an embodiment of the present disclosure are described below with reference to FIGS. 1-10. Referring to FIGS. 1 and 10, the DRAM device 10 includes a substrate 100, a plurality of word lines 104, a bit line contact 21, a dummy bit line 13, a bit line 23, and a capacitor contact structure 610. The substrate 100 includes an array region A1, a peripheral region A2, and a dummy region AD between the array region A1 and the peripheral region A2. Furthermore, the substrate 100 may include a plurality of doped regions serving as the active region 101. An isolation structure 102 surrounding the active region 101 and a plurality of word lines 104 may be formed in the substrate 100.

In some embodiments, each bit line 23 and each dummy bit line 13 may extend along the first direction D1, and the bit lines 23 and the dummy bit lines 13 may be arranged along the third direction D3. The first direction D1 is, for example (but not limited to), perpendicular to the second direction D2. Furthermore, each word line 104 may extend along the third direction D3, that is, the word line 104 may intersect the bit line 23, and the word lines 104 may be arranged along the first direction D1. In one embodiment, the extension direction of each active region 101 may form an angle (e.g., about 10° to 40°) with the third direction D3 to increase the integration. In some embodiments, each active region 101 may intersect two word lines 104 and one bit line 23, and may be electrically connected to the upper bit line 23 through a bit line contact 21. In a top view, the bit line contacts 21 may be disposed in a staggered manner, and may be disposed spaced apart from the word line 104 in the extending direction of the bit line 23 (e.g., in the first direction D1).

In some embodiments, the word line 104 may be formed in the substrate 100 such that its top surface is lower than the top surface of the substrate 100, and thus may be referred to as a buried word line. Each word line 104 may include a gate dielectric layer, a barrier layer, and a conductive layer sequentially formed in a trench. The word line 104 may be formed using structures and methods known in the art. After forming the word lines 104 in the trenches, an insulating layer may be formed over each word line 104 to fill the remaining gaps in the trenches, such that the top surface of the insulating layer is substantially coplanar with the top surface of the substrate 100.

The present disclosure provides a new DRAM device and a manufacturing method thereof to address the problem of improper penetration of etchant beyond a predetermined range of an array region when removing a sacrificial oxide layer in a conventional manufacturing process. Therefore, compared with the conventional process, the manufacturing method provided in the embodiment of the present disclosure may accurately define the area of the array region and reduce the number of dummy features (or the region of the dummy region AD). The following is a description of the manufacturing methods of DRAM devices according to some embodiments of the present disclosure with reference to the figures.

Referring to FIG. 2, the material of the substrate 100 may include a semiconductor material, such as silicon, gallium arsenide, gallium nitride, germanium silicide, or a combination thereof. In another embodiment, the substrate 100 may be a silicon-on-insulator (SOI) substrate. In this disclosure, forming the film layer blanketly refers to a process in which the resulting film layer covers both the array region A1 and the peripheral region A2. The isolation structure 102 may be a shallow trench isolation structure, for example, including an isolation liner and an isolation filler formed in sequence. The isolation liner and the isolation filler may include nitride or oxide, such as silicon oxide, silicon nitride, silicon oxynitride, and/or a combination thereof. It is understood that the present disclosure may utilize any known isolation structure 102 and manufacturing methods thereof.

According to some embodiments, a plurality of bit line stack structures 230 are formed over the substrate 100. In some embodiments, the bit line stack structure 230 includes a bit line layer 24 on the substrate 100 and a mask layer 25 on the bit line layer 24. The bit line layer 24, for example, includes a semiconductor material layer 241 and a conductive material layer 243 in sequence.

In some embodiments, the semiconductor material layer 241 may be an undoped semiconductor layer, a doped semiconductor layer, or a polysilicon layer. The bit line contact 21 may extend into the substrate 100 and may include polysilicon, metal, or metal nitride. The conductive material layer 243 may include a first conductive material layer on the semiconductor material layer 241 and a second conductive material layer on the first conductive material layer. The first conductive material layer and the second conductive material layer may include undoped or doped polysilicon, metal, or metal nitride, such as tungsten (W), titanium (Ti), or titanium nitride (TiN). The resistance of the second conductive material layer above the first conductive material is, for example, lower than the resistance of the semiconductor material layer 241. In some examples, the semiconductor material layer 241 is, for example, polysilicon, and the first conductive material layer and the second conductive material layer of the conductive material layer 243 are a titanium nitride layer and a metal tungsten layer, respectively. The mask layer 25 may include nitride, oxide, or a combination thereof.

In addition, a plurality of device structures 32 may be formed in the peripheral region A2. The device structure 32 may be, for example, a gate stack of a transistor device. In one embodiment, the device structure 32 includes a gate oxide layer 320, a semiconductor layer 321 (e.g., a polysilicon layer), a first gate conductive layer 322 (e.g., a titanium nitride layer), a second gate conductive layer 323 (e.g., a metal tungsten layer), and a hard mask layer 325 (e.g., a silicon nitride layer) sequentially formed on the substrate 100. Furthermore, spacers 326 are formed on the sidewalls of the device structures 32. It is understood that the present disclosure may utilize any known device structure 32 and manufacturing methods thereof, and the present disclosure is not limited thereto.

In addition, in some embodiments, when forming the bit line stack structure 230, the corresponding bit line contact 21 and the substrate 100 around it are partially removed to form a recess surrounding each bit line contact 21. The recesses expose a portion of the active region 101 and a portion of the isolation structure 102.

Afterwards, spacer structures 27 may be formed on the sidewalls of the bit line stack structures 230 and in the recesses. As a result, a plurality of bit line structures 231 including the bit line stack structures 230 and the spacer structures 27 are formed. The spacer structure 27 may include a combination of different dielectric materials, such as a first spacer material layer 271, a second spacer material layer 272, and a third spacer material layer 273. In some embodiments, the recess may be filled with a first spacer material layer 271, and a second spacer material layer 272 may be formed on the sidewalls of the bit line stack structure 230. The second spacer material layer 272 may also be formed on the first spacer material layer 271. The third spacer material layer 273 may be conformally formed on the second spacer material layer 272. The first spacer material layer 271, the second spacer material layer 272, and the third spacer material layer 273 may each include, for example, silicon oxide, silicon nitride, other suitable dielectric materials, air gaps, or a combination thereof. In some embodiments, the third spacer material layer 273 and the second spacer material layer 272 may include different materials. For example, the third spacer material layer 273 is a silicon nitride layer. An insulating material layer 26 may be formed on the third spacer material layer 273 to fill the gap between the bit line structures 231, such that the insulating material layer 26 does not overlap with the vertical projection of the word lines 104. The top surface 273a of the third spacer material layer 273 may be coplanar with the top surface 26a of the insulating material layer 26.

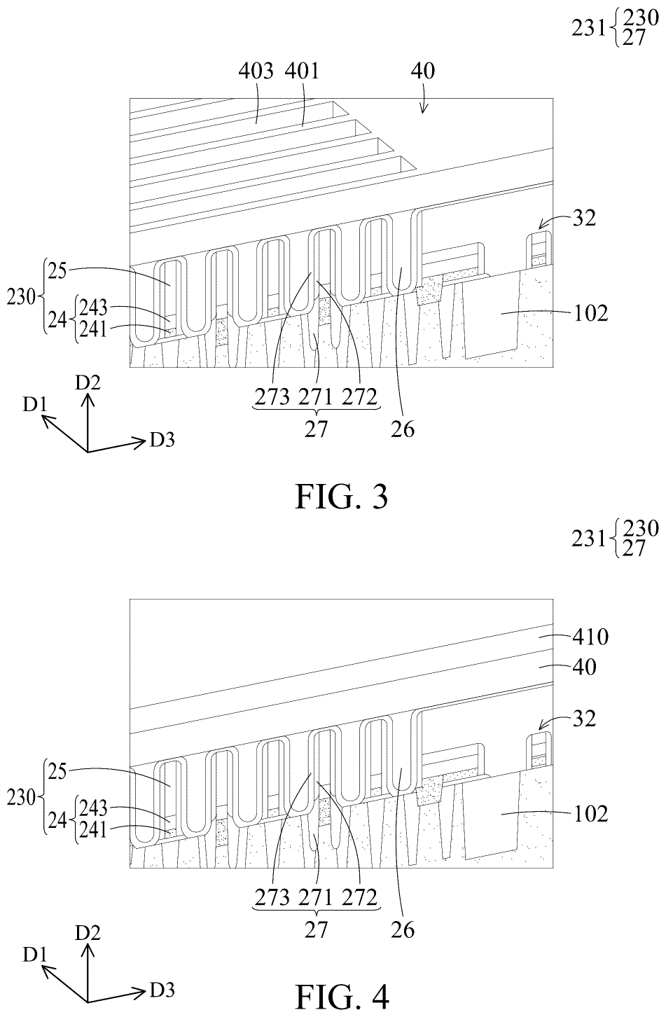

Next, referring to FIG. 3, according to some embodiments, a patterned mask 40 is formed over the bit line structures 231 and the insulating material layer 26. The patterned mask 40 includes a plurality of strip patterns 401 and openings 403 formed between the strip patterns 401. The extending direction of the strip pattern 401 is different from (for example, but not limited to perpendicular to) the extending direction of the bit line structure 231. For example, if each bit line structure 231 extends in the first direction D1, each strip pattern 401 may extend in the third direction D3. The opening 403 may overlap with the vertical projection of the word lines 104. The opening 403 exposes a portion of the bit line structure 231 and the insulating material layer 26, and an end thereof may expose a portion of the insulating material layer 26 closest to the peripheral region A2. The strip pattern 401 and the bit line structure 231 are used to define the location of the node contact plug 611 (shown in FIG. 10) of the DRAM device. In this embodiment, the patterned mask 40 may cover the peripheral region A2, and the openings 403 do not expose the device structure 32.

Next, referring to FIG. 4, according to some embodiments, a first dielectric layer 410 is blanketly formed over the patterned mask 40 to fill the openings 403 between the strip patterns 401. The first dielectric layer 410 and the stripe pattern 401 include different materials. For example, the first dielectric layer 410 includes nitride, and the stripe pattern 401 includes oxide.

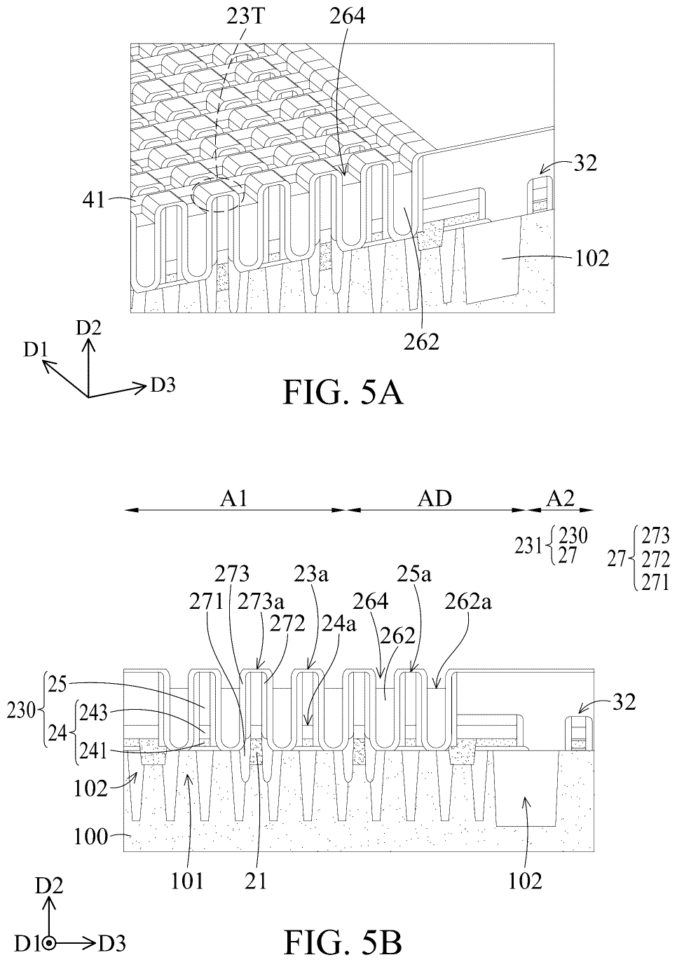

Next, referring to FIGS. 5A and 5B, the first dielectric layer 410 is etched back to expose the strip patterns 401, and the remaining first dielectric layer 41 still fill the gaps 403 between the strip patterns 401. Then, the strip pattern 401 is removed to expose the insulating material layer 26 underneath. Next, according to some embodiments of the present disclosure, the insulating material layer 26 can be further recessed, for example, by an etch-back process, to expose the top portions 23T of the bit line structures 231, and to form a recessed insulating material layer 262 between the bit line structures 231. As shown in FIG. 5B, in some embodiments, the top surface 262a of the recessed insulating material layer 262 is lower than the top surface 23a of the bit line structure 231, such as lower than the top surface 25a of the mask layer 25, and higher than the top surface 24a of the bit line layer 24.

Specifically, after the insulating material layer 26 is recessed, the remaining first dielectric layer 41, the top portions 23T of two adjacent bit line structures 231 and the top surface 262a of the recessed insulating material layer 262 therebetween collectively define a recess 264. According to the present disclosure, the recessed insulating material layer 262 is recessed to such an extent that, for example, the top portions 23T of the bit line structures 231 nearby the peripheral region A2 can be exposed, so that a subsequently formed cap layer 42 (as shown in FIG. 9) may at least fill the recesses 264 nearby the peripheral region A2 and function as a protective cap for the recessed insulating material layer 262.

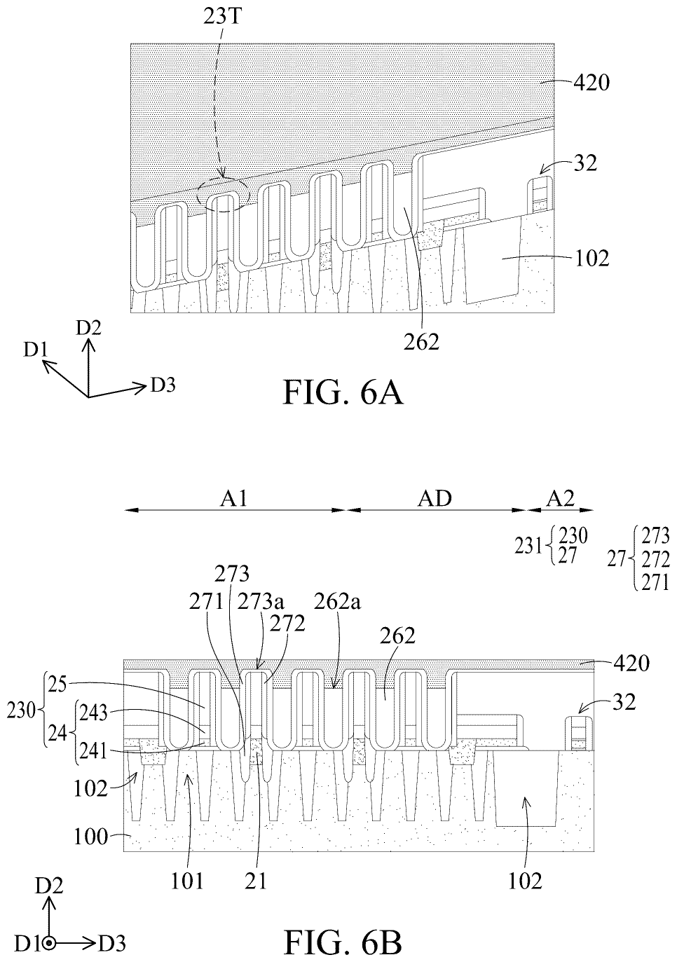

Next, referring to FIGS. 6A and 6B, a second dielectric layer 420 is blanketly formed on the remaining first dielectric layer 41 and the recessed insulating material layer 262. The second dielectric layer 420 fills the recesses 264 over the recessed insulating material layer 262. As a result, the second dielectric layer 420 may cover the top portions 23T of the bit line structures 231. In certain embodiments, the second dielectric layer 420 may encapsulate the upper portions 23T of the bit line structures 231 to enhance protection.

In some embodiments, the second dielectric layer 420 and the insulating material layer 26 include different materials. The second dielectric layer 420 may include a material that is denser than the insulating material layer 26 and has a relatively high etching resistance to the etchant for removing the insulating material layer 26, so as to form a protective sealing cap over the recessed insulating material layer 262. For example, the insulating material layer 26 may include silicon oxide, and the second dielectric layer 420 may include silicon nitride.

According to an embodiment of the present disclosure, after forming the second dielectric layer 420 over the bit line structure 231 and the recessed insulating material layer 262 and filling the recesses 264, the area of active bits in the array region A1 is further defined.

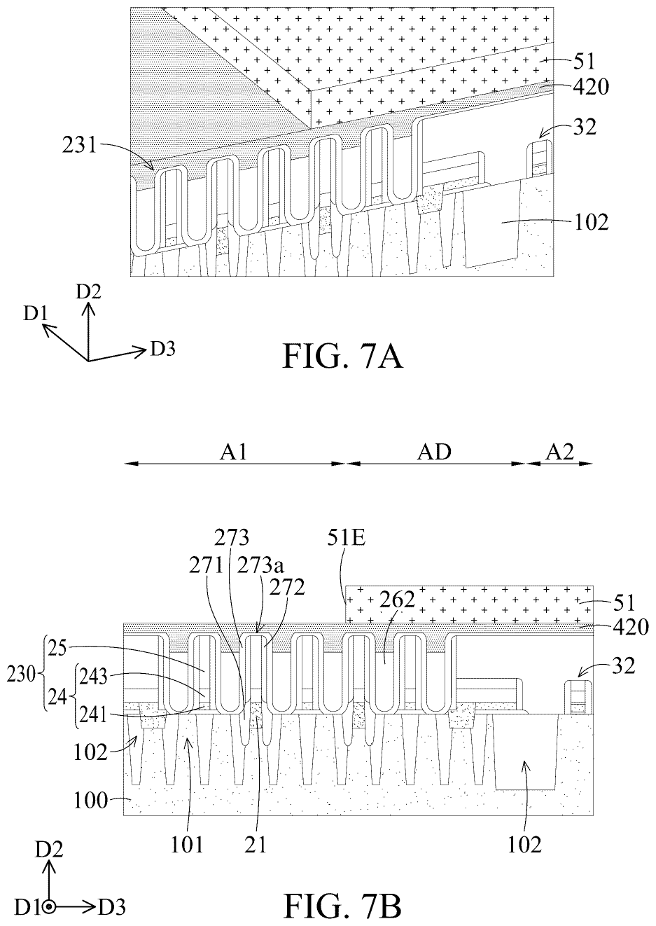

Referring to FIGS. 7A and 7B, according to some embodiments, a photoresist pattern 51 is formed on the second dielectric layer 420. The photoresist pattern 51 may cover the dummy region AD and the peripheral region A2, with an opening corresponding to the array region A1. Specifically, the photoresist pattern 51 is separated from the underlying bit line structure 231 and the recessed insulating material layer 262 by the second dielectric layer 420.

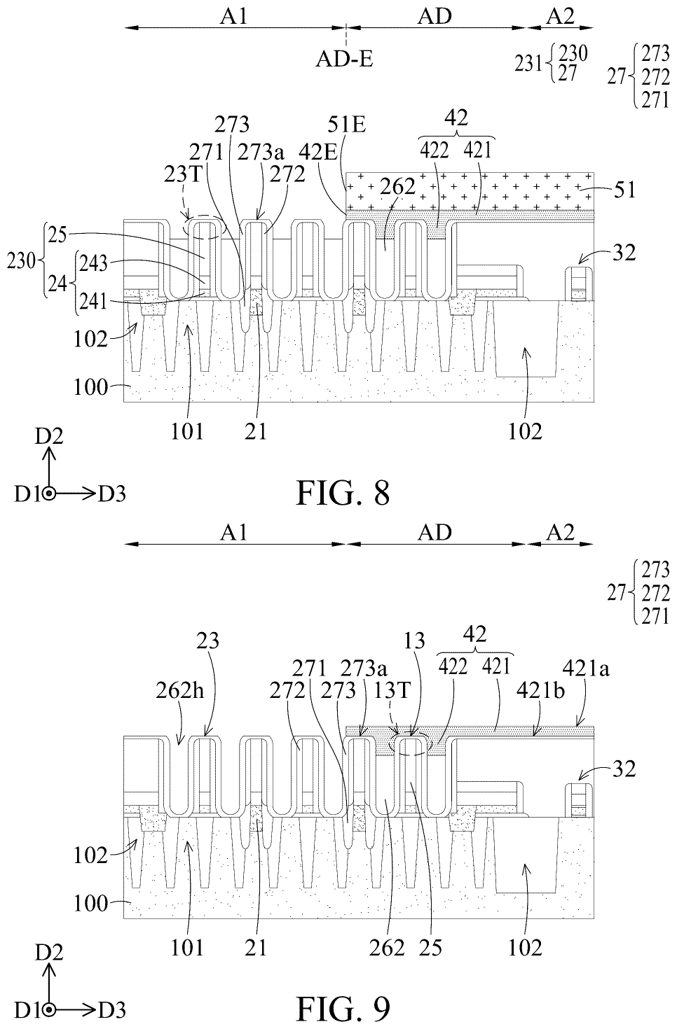

Next, referring to FIG. 8, according to some embodiments, the second dielectric layer 420 is patterned using the photoresist pattern 51 as an etching mask to remove the second dielectric layer 420 in the array region A1, and the remaining portion of the second dielectric layer 420 forms the cap layer 42. For example, the portion of the second dielectric layer 420 exposed by the opening of the photoresist pattern 51 is removed by dry etching to expose the top portions 23T of the bit line structures 231 and the recessed insulating material layer 262 in the array region A1. The cap layer 42 covers the bit line structures 231 in the dummy region AD and fills the recesses 264 over the recessed insulating material layer 262 in the dummy region AD. In some embodiments, the edge 42E of the cap layer 42 is substantially aligned with the edge 51E of the photoresist pattern 51, and is also substantially aligned with the inner edge AD-E of the dummy region AD.

Next, referring to FIG. 9, the recessed insulating material layer 262 in the array region A1 is removed by using the cap layer 42 as a mask to form node contact holes 262h. In one embodiment, the substrate 100 may be further etched so that the node contact hole 262h extends into the substrate 100. The recessed insulating material layer 262 may be removed by immersion through a wet etching process. In some embodiments, the etchant used in the aforementioned wet etching process selectively remove the insulating material layer 26 while not substantially affecting the cap layer 42. In the present disclosure, the cap layer 42 blocks the etchant from penetrating into the dummy region AD during the process of forming the node contact holes 262h, thereby preventing the recessed insulating material layer 262 in the dummy region AD from being etched. After the node contact holes 262h are formed, the dummy region AD still retains the recessed insulating material layer 262, which forms dummy insulating structures separated from each other along the first direction D1). Afterwards, the photoresist pattern 51 may be removed by, for example, an ashing process, and the cap layer 42 remains.

According to an embodiment of the present disclosure, as shown in FIG. 9, the cap layer 42 is in the dummy region AD but not in the array region A1, and the bit line structure 231 covered by the cap layer 42 is called as a dummy bit line 13. In contrast, the bit line structures 231, which are in the array region A1 and not covered by the capping layer 42, is called as the bit line 23. The cap layer 42 includes a body portion 421 and protruding portions 422. The body portion 421 covers the top surface 13a of the dummy bit line 13, specifically, the body portion 421 may cover the top of the third spacer material layer 273). The protruding portion 422 protrudes from the bottom surface 421b of the body portion 421 and fills the gap between the top portions 13T of the dummy bit lines 13 (i.e., the recess 264 over the insulating material layer 262) to serve as a seal on the recessed insulating material layer 262. The body portion 421 of the cap layer 42 is not only in the dummy region AD, but also may extend to the peripheral region A2. The top surface of the cap layer 42 (e.g., the top surface 421a of the body portion 421) is higher than the top surface of the bit line 23. Specifically, the top surface 421a of the body portion 421 of the cap layer 42 is higher than the top surface of the spacer structure 27 (e.g., the top surface 273a of the third spacer material layer 273). Furthermore, the top surface 421a of the body portion 421 is a substantially flat surface and may have good adhesion with the photoresist pattern 51 subsequently formed thereon.

Next, as shown in FIG. 10, a node contact plug 611 may be formed in the node contact hole 262h, which is at one side of the bit line 23 and contacts the active region 101. The height of the top surface of the node contact plug 611 may be between the top surface and the bottom surface of the mask layer 25, but the invention is not limited thereto. In some embodiments, the node contact plug 611 includes conductive material, for example, doped polysilicon, metal, or metal nitride, metal silicide, or a combination thereof. In this embodiment, the node contact plug 611 includes a doped polysilicon layer 611′ and a metal silicide layer 612 (e.g., cobalt silicide (CoSi)) formed in sequence to reduce subsequent contact resistance. In the third direction D3, the dummy insulating structure 262 is arranged along with the node contact plugs 611. The node contact plug 611 can be positioned so that its bottom surface is lower than the bottom surface of the dummy insulating structure 262, thereby electrically connecting it to the active region 101 of the substrate 100 and reducing impedance.

Next, according to some embodiments, landing pads 615 each including a barrier layer 613 and a conductive layer 614 may be formed on the node contact plugs 611 and the bit lines 23. The barrier layer 613 may include metal nitride, such as titanium nitride (TiN). The conductive layer 614 may include doped polysilicon, metal, or metal nitride, such as metal tungsten (W). The landing pad 615 is used to electrically connect the node contact plug 611 to a capacitor subsequently formed. Herein, the landing pad 615 and the node contact plug 611 are collectively referred to as a capacitor contact structure 610. The capacitor contact structure 610 is electrically connected to the active region 101. Afterwards, an insulating member 620 is formed between two adjacent landing pads 615. Furthermore, according to some embodiments, the top surface 262a of the dummy insulating structure 262 may be higher than the top surface 611a of the node contact plug 611.

After forming the capacitor contact structure 610, any known components such as capacitors, metal layers, etc., may be formed to complete the manufacturing of the DRAM device 10. It is noted that each of the steps described in the above embodiments, or variations thereof, may further include other known applicable processes. For purposes of clarity and brevity, certain known processes have been omitted from the figures and detailed description.

As shown in FIG. 10, the dram device 10 proposed in some embodiments of the present disclosure has a cap layer 42 having a plurality of protruding portions 422 extending downward between the dummy bit lines 13 and filling the recess 264 to form a protective sealing cover over the dummy insulating structure 262. Thus, when removing the recessed insulating material layer 262 in the array region A1, the cap layer 42 may prevent the etchant from penetrating into the region outside the active bit, that is, the etchant does not penetrate into the dummy region AD, and may protect the dummy bit line 13 and the dummy insulating structure 262 in the dummy region AD. Therefore, the photoresist pattern 51 shown in FIG. 7A may accurately define the area of the active bits to be formed, thereby reducing the number of dummy bits. The following are examples and illustrations.

Referring to FIG. 11, a partial top view of an array region A1 and a peripheral region A2 of a DRAM device according to some embodiments of the present disclosure is illustrated. FIG. 11 illustrates an embodiment in which the cap layer 42 and the photoresist pattern 51 surround the array region A1, and the edge 42E of the cap layer 42 is substantially aligned with the edge 51E of the photoresist pattern 51.

In conventional manufacturing methods, during the process of forming the node contact hole, the etchant may penetrate from the bottom edge of the photoresist pattern, resulting undesirably removing the insulating material layer under the photoresist pattern. The closer the insulating material layer is to the edge of the photoresist pattern, the deeper the void depth generated after the node contact hole is formed. Since the conventional manufacturing method fails to mitigate this penetration problem, the conventional approach is to increase the coverage of the photoresist pattern (e.g., the edge E0 to the dotted line E2 of the conventional photoresist pattern is the area of the conventional dummy region). However, this also sacrifices the area of the array region A1, thereby reducing the number of active bits and increasing the cost. Furthermore, the voids generated after forming the node contact holes will be filled with conductive materials in the subsequent process. As the voids deepen, the filled conductive material gets closer to the substrate, raising the risk of a leakage path forming.

The cap layer 42 of this embodiment may block the penetration of the etchant. In combination with the photoresist pattern 51, the cap layer 42 enables accurate definition of the active bit region (in the array region A1) without concerns regarding etchant penetration, thereby simplifying the process and reducing processing time. Therefore, compared with the edge E0 of the conventional photoresist pattern, the edge 51E of the photoresist pattern 51 may be closer to the peripheral region A2 (the edge 51E to the dotted line E2 is the area of the dummy region AD in this embodiment). That is, the area for forming active bits may be further expanded outward, thereby increasing the number of active bits that may be formed and reducing the number of dummy bits. Furthermore, the cap layer 42 may protect the recessed insulating material layer 262 in the dummy region AD from being etched away, so that the recessed insulating material layer 262 will not be filled with conductive material and lead to leakage paths in subsequent processes, thereby improving product yield. In addition, the amplified region obtained by applying this embodiment (i.e., the area from edge E0 to edge 51E) may be used to dispose other components, such as disposing repair bits to repair defects of the DRAM device 10, thereby improving the yield. Furthermore, the present embodiment may accurately define the area of the array region A1 and reduce the range of the dummy region AD, thus facilitating the scaling of the DRAM device 10.

Compared with conventional processes, the present embodiment may increase the number of active bits, thereby enabling each wafer to yield a greater number of memory bits, such that fewer wafers are required to meet production demand. Therefore, the present invention may reduce process production costs and energy consumption, thereby reducing carbon emissions, water resources, and chemical usage in the production process of each unit of DRAM device. In addition, since the yield of the DRAM device and the manufacturing method thereof of the present invention are improved, waste in the manufacturing process is reduced. Therefore, the present invention provides a green semiconductor technology.

What is claimed is:

1. A dynamic random access memory device, comprising:
a substrate comprising an array region, a peripheral region, and a dummy region between the array region and the peripheral region;
a plurality of bit lines over the substrate in the array region;
a plurality of node contact plugs in the array region, each of the node contact plugs located on the substrate at one side of a corresponding one of the bit lines;
a plurality of dummy bit lines over the substrate in the dummy region;
a dummy insulating structure between the dummy bit lines, wherein the dummy insulating structure is arranged along with the node contact plugs; and
a cap layer outside the array region to cover top portions of the dummy bit lines and a top portion of the dummy insulating structure.

2. The dynamic random access memory device as claimed in claim 1, wherein
a top surface of the dummy insulating structure is lower than top surfaces of the dummy bit lines, and
the cap layer comprises:
a body portion covering the top surfaces of the dummy bit lines, and having a top surface higher than the top surface of the bit lines; and
a plurality of protruding portions protruding from a bottom surface of the body portion to fill a recess on the dummy insulating structure.

3. The dynamic random access memory device as claimed in claim 1, further comprising:
a plurality of landing pads formed on the bit lines and the node contact plugs and electrically connected to the node contact plugs respectively, wherein
each of the bit lines comprises a spacer structure on sidewalls of each of the bit lines, and a top surface of the cap layer is higher than a top surface of the spacer structure.

4. The dynamic random access memory device as claimed in claim 3, wherein each of the bit lines and each of the dummy bit lines comprises:
a bit line layer over the substrate; and
a mask layer on the bit line layer, wherein
the top surface of the dummy insulating structure is lower than a top surface of the mask layer.

5. The dynamic random access memory device as claimed in claim 4, wherein the top surface of the dummy insulating structure is higher than a top surface of the bit line layer.

6. The dynamic random access memory device as claimed in claim 1, wherein the cap layer and the dummy insulating structure comprise different materials.

7. The dynamic random access memory device as claimed in claim 3, wherein a top surface of the dummy insulating structure is higher than a top surface of the node contact plug.

8. The dynamic random access memory device as claimed in claim 1, wherein the cap layer comprises nitride and has a top surface higher than the top surface of the bit lines.

9. The dynamic random access memory device as claimed in claim 1, wherein the cap layer is located in the dummy region and the peripheral region to cover a plurality of device structures in the peripheral region.

10. A method for manufacturing a dynamic random access memory device, comprising:
forming a plurality of bit line structures over a substrate in an array region and in a dummy region outside the array region;
forming an insulating material layer between the bit line structures;
forming a cap layer in the dummy region and exposing the array region, wherein the bit line structures covered by the cap layer forms a plurality of dummy bit lines, the bit line structures exposed by the cap layer forms a plurality of bit lines, and the insulating material layer covered by the cap layer forms a dummy insulating structure;
removing the insulating material layer exposed by the cap layer to form a plurality of node contact holes in the array region; and
forming a plurality of node contact plugs in the node contact holes, each of the node contact plugs located on the substrate at one side of a corresponding one of the bit lines, wherein the dummy insulating structure is arranged along with the node contact plugs.

11. The method for manufacturing the dynamic random access memory device as claimed in claim 10, further comprising:
recessing the insulating material layer before forming the cap layer, such that a top surface of the dummy insulating structure is lower than the top surface of the bit line structure,
wherein the cap layer comprises:
a body portion covering top surfaces of the dummy bit lines, and having a top surface higher than the top surface of the bit lines; and
a plurality of protruding portions protruding from a bottom surface of the body portion to fill a recess on the dummy insulating structure.

12. The method for manufacturing the dynamic random access memory device as claimed in claim 10, further comprising:
forming a plurality of landing pads formed on the bit lines and the node contact plugs and electrically connected to the node contact plugs respectively, wherein
each of the bit lines comprises a spacer structure on sidewalls of each of the bit lines, and a top surface of the cap layer is higher than a top surface of the spacer structure.

13. The method for manufacturing the dynamic random access memory device as claimed in claim 11, wherein recessing the insulating material layer before forming the cap layer comprises:
forming a patterned mask over the bit line structures and the insulating material layer having a top surface coplanar with a top surface of the bit line structures, wherein the patterned mask comprises a plurality of strip patterns and a plurality of openings between the strip patterns, and an extending direction of each of the strip patterns is different from an extending direction of each of the bit line structures;
forming a first dielectric layer on the patterned mask blanketly, wherein the first dielectric layer fills openings between the strip patterns;
removing a portion of the first dielectric layer to expose the strip patterns;
removing the strip patterns to expose the insulating material layer; and
recessing the insulating material layer to expose top portions of the bit line structures, thereby forming the recessed insulating material layer between the bit line structures.

14. The method for manufacturing the dynamic random access memory device as claimed in claim 10, wherein each of the bit lines and each of the dummy bit lines comprises:
a bit line layer over the substrate; and
a mask layer on the bit line layer, wherein
a top surface of the dummy insulating structure is lower than a top surface of the mask layer.

15. The method for manufacturing the dynamic random access memory device as claimed in claim 14, wherein the top surface of the dummy insulating structure is higher than a top surface of the bit line layer.

16. The method for manufacturing the dynamic random access memory device as claimed in claim 10, wherein the cap layer and the insulating material layer comprise different materials.

17. The method for manufacturing the dynamic random access memory device as claimed in claim 10, wherein the insulating material layer exposed by the cap layer is removed by wet etching using an etchant with a high selectivity to the cap layer and the insulating material layer.

18. The method for manufacturing the dynamic random access memory device as claimed in claim 12, wherein a top surface of the dummy insulating structure is higher than a top surface of the node contact plug.

19. The method for manufacturing the dynamic random access memory device as claimed in claim 10, wherein the cap layer comprises nitride and has a top surface higher than the top surface of the bit lines.

20. The method for manufacturing the dynamic random access memory device as claimed in claim 10, wherein the cap layer is located in the dummy region and a peripheral region to cover a plurality of device structures in the peripheral region, and the dummy region is between the array region and the peripheral region.
